(19) United States
(12) Patent Application Publication
(10) Pub. No.: US 2024/0298509 A1
(43) Pub. Date: Sep. 5, 2024

(54) DISPLAY PANEL AND DISPLAY DEVICE

(71) Applicant: Wuhan China Star Optoelectronics Semiconductor Display Technology Co., Ltd., Wuhan (CN)

(72) Inventors: Wenliang GONG, Wuhan (CN); Song JIANG, Wuhan (CN)

(21) Appl. No.: 17/293,521

(22) PCT Filed: Mar. 31, 2021
(86) PCT No.: PCT/CN2021/084594

§ 371 Date: May 11, 2024

(30) Foreign Application Priority Data
May 13, 2001 (CN) 202110321140.9

(51) Int. Cl. H10K 59/80; H10K 59/122; H10K 59/40

(52) U.S. Cl. CPC H10K 59/8792; H10K 59/122; H10K 59/40

(57) ABSTRACT

A display panel and a display device provided by the present invention replace a polarizer with a light-absorbing structure formed by a black material adopted by a pixel defining layer. The light-absorbing structure is configured to absorb light reflected by touch control electrodes. The light-shielding structure is disposed on a side of a color filter layer to block, absorb, and reflect light reflected by an upper surface of the touch control electrodes. Because the polarizer does not need to be provided, a light extraction rate of a light-emitting layer is increased while reducing reflectance of an upper surface of the pixel defining layer. A black matrix layer does not need to be provided, or even if the black matrix layer is provided, a size of an opening of the black matrix layer is larger than a size of a slot of the pixel defining layer, thereby increasing an aperture ratio.

### FIELD OF INVENTION

The present invention is related to the field of display technology and specifically to a display panel and a display device.

### BACKGROUND OF INVENTION

Polarizers (POLs) can effectively reduce reflectance of display panels under strong light, but nearly 58% of their emitted light will be lost. As a result, this greatly increases life burden of organic light-emitting diodes (OLEDs). In addition, the polarizers have characteristics of large thickness and brittle material, which are not conducive to development of dynamic bending products. In order to develop the dynamic bending products based on current OLED technology, new materials, new technologies, and new processes must be introduced to replace polarizers.

A method of using color filters (CFs) to replace POLs is classified as POL-less technology. It can not only reduce thicknesses of functional layers from about 100 μm to about 5 μm, but also increase a light extraction rate of OLEDs from 42% to 60%.

However, compared with the polarizers, the color filters have higher surface reflectance and lower contrast under strong light, which is not conducive to outdoor display. A color filter is composed of red (R) color resists, green (G) color resists, blue (B) color resists, and a black matrix. in a display panel, R/G/B color resists are responsible for light extraction of corresponding R/G/B subpixel units of a light-emitting layer, and the black matrix mainly is responsible for preventing the display panel from light leakage and reducing reflection of the display panel.

In prior art, the black matrix is directly formed on a thin-film encapsulation, so brightness-viewing angles decay too fast when viewing angles increase, thereby detracting characteristics of the display panels.

### SUMMARY OF INVENTION

### Technical Problem

A purpose of the present invention is to provide a display panel and a display device that can effectively solve disadvantages of fast decay of brightness-viewing angles by adopting a black pixel defining layer to replace a black matrix on a thin-film encapsulation. This prevents technical problems of insufficient reflectivity characteristics and low contrast defects.

### Solution of Problem

### Technical Solution

In order to solve the above-mentioned problems, the present invention provides a display panel including an array substrate, a pixel defining layer, and a color filter layer. The pixel defining layer is disposed on the array substrate. The pixel defining layer adopts a black material. The color filter layer is disposed on the pixel defining layer. The color filter layer includes a light-shielding structure corresponding to the pixel defining layer.

Furthermore, an upper surface of the pixel defining layer away from the array substrate is defined with a concave-convex structure.

Furthermore, a cross section of the concave-convex structure is sawtooth-shaped. A groove or a protrusion of the concave-convex structure is trapezoidal or columnar.

Furthermore, a material of the pixel defining layer includes photosensitive polyimide.

Furthermore, the display panel further includes a plurality of touch control electrodes disposed between the pixel defining layer and the color filter layer and corresponding to the pixel defining layer.

Furthermore, the color filter layer includes a color resist layer. The color resist layer includes a plurality of color resist units. A projection of the touch control electrodes on the array substrate completely falls within a projection of the color resist units on the array substrate. The color resist units in a region corresponding to the touch control electrodes form the light-shielding structure.

Furthermore, two adjacent color resist units overlap each other to form the light-shielding structure. The light-shielding structure corresponds to a position of the touch control electrodes.

Furthermore, the color filter layer includes a black matrix layer. The black matrix layer is disposed between two adjacent color resist units. A width of the black matrix layer is less than a width of the pixel defining layer. The black matrix layer forms the light-shielding structure.

Furthermore, the pixel defining layer includes a plurality of slots. A width of each of the slots is less than a width of each of the color resist units.

The present invention further provides a display device including any one of the above-mentioned display panels.

### BENEFICIAL EFFECT OF INVENTION

### Beneficial Effect

The present invention provides the display panel and the display device. An advantage is that the light-absorbing structure formed by the black material adopted by the pixel defining layer can replace a polarizer. The light-absorbing structure is configured to absorb light reflected by the touch control electrodes. The light-shielding structure is disposed on a side of the color filter layer to block, absorb, and reflect light reflected by an upper surface of the touch control electrodes. Because the polarizer does not need to be provided, a light extraction rate of a light-emitting layer is increased while reducing reflectance of the upper surface of the pixel defining layer. Therefore, the black matrix layer does not need to be provided, or even if the black matrix layer is provided, a size of each of openings of the black matrix layer is larger than a size of each of the slots of the pixel defining layer, thereby increasing an aperture ratio.

### BRIEF DESCRIPTION OF DRAWINGS

### Description of Drawings

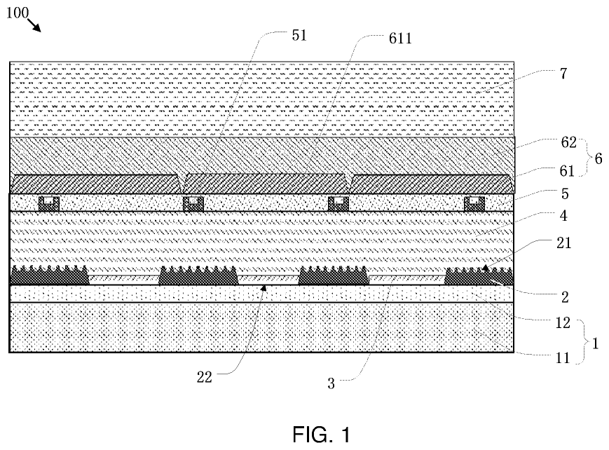

FIG. 1 is a structural schematic diagram of an organic light-emitting diode display panel in a first embodiment of the present invention.

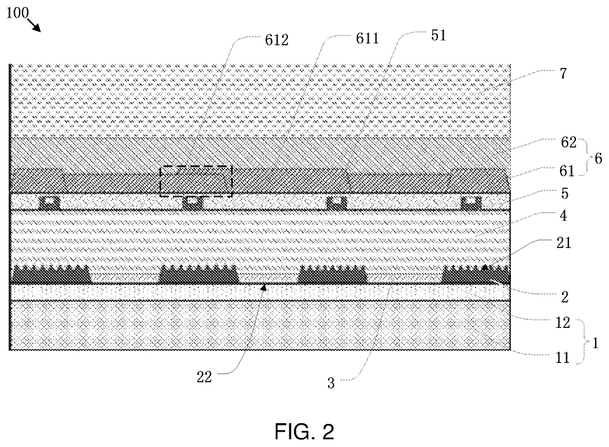

FIG. 2 is a structural schematic diagram of an organic light-emitting diode display panel in a second embodiment of the present invention.

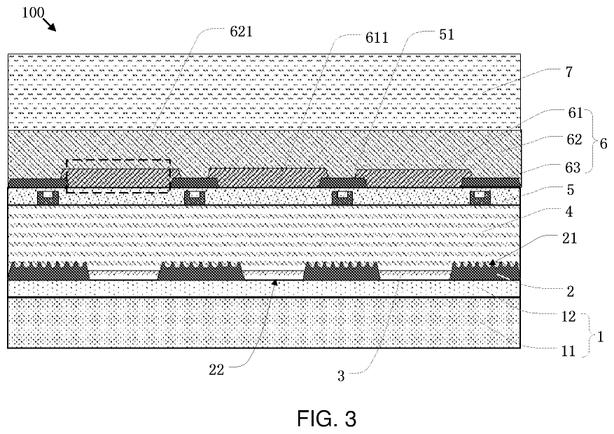

FIG. 3 is a structural schematic diagram of functional layers produced in a third embodiment.

### REFERENCE SIGNS

array substrate 1, pixel defining layer 2, light-emitting layer 3,
encapsulation layer 4, touch control layer 5, color filter layer 6,
cover plate 7, light-absorbing structure 21, slots 22,
touch control electrodes 51, color resist layer 61, optical adhesive layer 62,
black matrix layer 63, display panel 100, color resist unit 611,
overlapping region 612, and opening 621.

### DETAILED DESCRIPTION OF EMBODIMENTS

### Embodiments of Invention

In the present invention, unless explicitly stated and limited, the first feature is “on” or “under” the second feature may refer to that the first feature and second feature are directly contact, or are indirectly through another feature between them. Moreover, the first feature is “above”, “upon”, and “upper” the second feature, including that the first feature is directly above and obliquely above the second feature refers to that t the first feature is higher in level than the second feature. The first feature is “below”, “down”, and “under” of the second feature refers to that the first feature is directly below or obliquely below the second feature, or merely refers to that the first feature is horizontally lower than the second feature.

In the present invention, a same or corresponding component in different figures uses a same reference sign. In this specification, the terms “first”, “second” and the like can be used to describe various components, and these components are not restricted to the above words. The above terms are merely used to separate a component from another component.

### First Embodiment

Please refer to FIG. 1. A first embodiment of the present invention provides a display panel 100 including an array substrate 1 and a pixel defining layer 2. The pixel defining layer 2 is disposed on the array substrate 1. The pixel defining layer 2 includes a black material. In other words, the black material adopted by the pixel defining layer 2 forms a light-absorbing structure 21. The light-absorbing structure 21 is a black nanostructure for absorbing light.

The array substrate 1 includes a flexible substrate layer 11 and a driving circuit layer 12 disposed on the flexible substrate layer 11. A material of the flexible substrate layer 11 is polyimide (PI) or hard glass and is preferably polyimide, which has flexibility. The pixel defining layer 2 is disposed on the driving circuit layer 12. A material of the pixel defining layer 2 is photosensitive polyimide (PSPI). The pixel defining layer 2 is defined with a plurality of slots 22 arranged at intervals. An upper surface of the pixel defining layer 2 away from the array substrate 1 is provided with an irregular or regular concave-convex structure. A cross section of the concave-convex structure is sawtooth-shaped. A groove or a protrusion of the concave-convex structure is trapezoidal or columnar. A cross-sectional width of the groove or the protrusion ranges from 150 nm to 250 nm and is preferably 200 nm.

The pixel defining layer 2 includes the plurality of slots 22. The display panel 100 further includes a light-emitting layer 3. The light-emitting layer 3 is disposed in the slots 22. The light-emitting layer 3 includes red light-emitting units, green light-emitting units, and blue light-emitting units.

The display panel 100 further includes an encapsulation layer 4. The encapsulation layer 4 is disposed on the pixel defining layer 2 and completely covers the light-emitting layer 3 for blocking water and oxygen.

The display panel 100 further includes a plurality of touch control electrodes 51. The touch control electrodes 51 are disposed on the encapsulation layer 4. The touch control electrodes 51 are a metal mesh structure composed of a metal mesh formed by a plurality of metal traces interlaced. The touch control electrodes 51 correspond to the light-absorbing structure 21. The light-absorbing structure 21 is configured to absorb light reflected by the touch control electrodes 51. Preferably, the touch control electrodes 51 are positioned in the touch control layer 5, and the touch control layer 5 is disposed on the pixel defining layer 2. The touch control electrodes 51 are disposed on the pixel defining layer 2 and correspond to the pixel defining layer 2. Preferably, the touch control electrodes 51 directly face the pixel defining layer 2.

The display panel 100 further includes a color filter layer 6 disposed on the touch control electrodes 51. The color filter layer 6 includes a light-shielding structure. The light-shielding structure corresponds to the light-absorbing structure 21. It is understandable that the color filter layer 6 is disposed on the pixel defining layer 2, and the touch control electrodes 51 are disposed between the color filter layer 6 and the pixel defining layer 2. The light-shielding structure can shield and absorb light reflected by an upper surface of the touch control electrodes 51 and can reflect part of the light to the light-absorbing structure 21. The light-absorbing structure 21 is positioned under the touch control electrodes 51 and can absorb light reflected by a lower surface of the touch control electrodes 51 and light reflected by the light-shielding structure.

The color filter layer 6 includes a color resist layer 61. The color resist layer 61 includes a plurality of color resist units 611. A projection of the touch control electrodes 51 on the array substrate 1 completely falls within a projection of the color resist units 611 on the array substrate 1. The color resist units 611 in a region corresponding to the touch control electrodes 51 form the light-shielding structure. The color resist units 611 include red filter units, green filter units, and blue filter units. The red filter units correspond to the red light-emitting units. The green filter units correspond to the green light-emitting units. The blue filter units correspond to the blue light-emitting units.

In this embodiment, the color resist units 611 are arranged adjacent to each other in a same layer, so that the color resist units 611 are arranged in the same layer without gaps. The color resist units 611 correspond to the touch control electrodes 51 and are responsible for absorbing the light reflected by the touch control electrodes 51, so that a black matrix layer (BM layer) may not be provided.

The color filter layer 6 further includes an optical adhesive layer 62 and a cover plate 7 of the display panel 100. The optical adhesive layer 62 is disposed on the color filter layer 6. The cover plate 7 is disposed on the optical adhesive layer 62.

Providing the light-absorbing structure 21 on the upper surface of the pixel defining layer 2 can increase a contact area between ambient light and the light-absorbing structure 21. In addition, the light-absorbing structure 21 is the black nanostructure, which can increase light absorbability to reduce specular reflection. The light reflected by the touch control electrodes 51 can be absorbed, so as to enhance screen contrast under this synergistic effect. The light-absorbing structure 21 is the concave-convex structure, which is similar to a prism to change light output angles of the display panel 100, thereby increasing viewing angles and increasing readability. Mainly, the black matrix layer may not be provided, thus reducing manufacturing costs of film layers and reducing an overall thickness of the display panel 100.

### Second Embodiment

Please refer to FIG. 2. A second embodiment of the present invention provides a display panel 100 including an array substrate 1 and a pixel defining layer 2. The pixel defining layer 2 is disposed on the array substrate 1. A surface of the pixel defining layer 2 away from the array substrate 1 is provided with a light-absorbing structure 21.

The array substrate 1 includes a flexible substrate layer 11 and a driving circuit layer 12 disposed on the flexible substrate layer 11. A material of the flexible substrate layer 11 is polyimide (PI) or hard glass and is preferably polyimide, which has flexibility. The pixel defining layer 2 is disposed on the driving circuit layer 12. A material of the pixel defining layer 2 is photosensitive polyimide (PSPI). The pixel defining layer 2 is defined with a plurality of slots 22 arranged at intervals. A black material adopted by the pixel defining layer 2 forms a light-absorbing structure 21. The light-absorbing structure 21 is a black nanostructure for absorbing light. An upper surface of the pixel defining layer 2 away from the array substrate 1 is provided with an irregular or regular concave-convex structure. A cross section of the concave-convex structure is sawtooth-shaped. A groove or a protrusion of the concave-convex structure is trapezoidal or columnar. A cross-sectional width of the groove or the protrusion ranges from 150 nm to 250 nm and is preferably 200 nm.

The pixel defining layer 2 includes the plurality of slots 22. The display panel 100 further includes a light-emitting layer 3. The light-emitting layer 3 is disposed in the slots 22. The light-emitting layer 3 includes red light-emitting units, green light-emitting units, and blue light-emitting units.

The display panel 100 further includes an encapsulation layer 4. The encapsulation layer 4 is disposed on the pixel defining layer 2 and completely covers the light-emitting layer 3 for blocking water and oxygen.

The display panel 100 further includes a plurality of touch control electrodes 51. The touch control electrodes 51 are a metal mesh structure composed of a metal mesh formed by a plurality of metal traces interlaced. The touch control electrodes 51 are disposed on the encapsulation layer 4. The touch control electrodes 51 correspond to the light-absorbing structure 21. The light-absorbing structure 21 is configured to absorb light reflected by the touch control electrodes 51. Preferably, the touch control electrodes 51 are positioned in the touch control layer 5, and the touch control layer 5 is disposed on the pixel defining layer 2. The touch control electrodes 51 are disposed on the pixel defining layer 2 and correspond to the pixel defining layer 2. Preferably, the touch control electrodes 51 directly face the pixel defining layer 2.

The display panel 100 further includes a color filter layer 6 disposed on the touch control electrodes 51. The color filter layer 6 includes a light-shielding structure. The light-shielding structure corresponds to the light-absorbing structure 21. It is understandable that the color filter layer 6 is disposed on the pixel defining layer 2, and the touch control electrodes 51 are disposed between the color filter layer 6 and the pixel defining layer 2. The light-shielding structure can shield and absorb light reflected by an upper surface of the touch control electrodes 51 and can reflect part of the light to the light-absorbing structure 21. The light-absorbing structure 21 is positioned under the touch control electrodes 51 and can absorb light reflected by a lower surface of the touch control electrodes 51 and light reflected by the light-shielding structure.

The color filter layer 6 includes a color resist layer 61. The color resist layer 61 includes a plurality of color resist units 611. A projection of the touch control electrodes 51 on the array substrate 1 completely falls within a projection of the color resist units 611 on the array substrate 1. The color resist units 611 include red filter units, green filter units, and blue filter units. The red filter units correspond to the red light-emitting units. The green filter units correspond to the green light-emitting units. The blue filter units correspond to the blue light-emitting units.

Two adjacent color resist units 611 overlap each other to form the light-shielding structure. Specifically, an overlapping region 612 is formed between two adjacent color resist units 611. A position of part of the touch control electrodes 51 corresponds to the overlapping region 612. The overlapping region 612 corresponds to the touch control electrodes 51 and is responsible for absorbing the light reflected by the touch control electrodes 51. The light-shielding structure is formed at a position of the overlapping region 612 and corresponds to a position of the touch control electrodes 51, so that a black matrix layer (black light-shielding layer) may not be provided.

The display panel 100 further includes an optical adhesive layer 62 and a cover plate 7. The optical adhesive layer 62 is disposed on the color filter layer 6. The cover plate 7 is disposed on the optical adhesive layer 62.

Providing the light-absorbing structure 21 on the upper surface of the pixel defining layer 2 can increase a contact area between ambient light and the light-absorbing structure 21. In addition, the light-absorbing structure 21 is the black nanostructure, which can increase light absorbability to reduce specular reflection. The light reflected by the touch control electrodes 51 can be absorbed, so as to enhance screen contrast under this synergistic effect. The light-absorbing structure 21 is the concave-convex structure, which is similar to a prism to change light output angles of the display panel 100, thereby increasing viewing angles and increasing readability. Meanwhile, the black matrix layer may not be provided because of the overlapping region 612 formed by overlapping two adjacent color resist units 611, thus reducing manufacturing costs of film layers and reducing an overall thickness of the display panel 100.

### Third Embodiment

Please refer to FIG. 3. A third embodiment of the present invention provides a display panel 100 including an array substrate 1 and a pixel defining layer 2. The pixel defining layer 2 is disposed on the array substrate 1. A surface of the pixel defining layer 2 away from the array substrate 1 is provided with a light-absorbing structure 21.

The array substrate 1 includes a flexible substrate layer 11 and a driving circuit layer 12 disposed on the flexible substrate layer 11. A material of the flexible substrate layer 11 is polyimide (PI) or hard glass and is preferably polyimide, which has flexibility. The pixel defining layer 2 is disposed on the driving circuit layer 12. A material of the pixel defining layer 2 is photosensitive polyimide (PSPI). The pixel defining layer 2 is defined with a plurality of slots 22 arranged at intervals. A black material adopted by the pixel defining layer 2 forms a light-absorbing structure 21. The light-absorbing structure 21 is a black nanostructure for absorbing light. An upper surface of the pixel defining layer 2 away from the array substrate 1 is provided with an irregular or regular concave-convex structure. A cross section of the concave-convex structure is sawtooth-shaped. A groove or a protrusion of the concave-convex structure is trapezoidal or columnar. A cross-sectional width of the groove or the protrusion ranges from 150 nm to 250 nm and is preferably 200 nm.

The pixel defining layer 2 includes the plurality of slots 22. The display panel 100 further includes a light-emitting layer 3. The light-emitting layer 3 is disposed in the slots 22. The light-emitting layer 3 includes red light-emitting units, green light-emitting units, and blue light-emitting units.

The display panel 100 further includes an encapsulation layer 4. The encapsulation layer 4 is disposed on the pixel defining layer 2 and completely covers the light-emitting layer 3 for blocking water and oxygen.

The display panel 100 further includes a plurality of touch control electrodes 51. The touch control electrodes 51 are a metal mesh structure composed of a metal mesh formed by a plurality of metal traces interlaced. The touch control electrodes 51 are disposed on the encapsulation layer 4. The touch control electrodes 51 correspond to the light-absorbing structure 21. The light-absorbing structure 21 is configured to absorb light reflected by the touch control electrodes 51. Preferably, the touch control electrodes 51 are positioned in the touch control layer 5, and the touch control layer 5 is disposed on the pixel defining layer 2. The touch control electrodes 51 are disposed on the pixel defining layer 2 and correspond to the pixel defining layer 2. Preferably, the touch control electrodes 51 directly face the pixel defining layer 2.

The display panel 100 further includes a color filter layer 6 disposed on the touch control electrodes 51. The color filter layer 6 includes a light-shielding structure. The light-shielding structure corresponds to the light-absorbing structure 21. It is understandable that the color filter layer 6 is disposed on the pixel defining layer 2, and the touch control electrodes 51 are disposed between the color filter layer 6 and the pixel defining layer 2. The light-shielding structure can shield and absorb light reflected by an upper surface of the touch control electrodes 51 and can reflect part of the light to the light-absorbing structure 21. The light-absorbing structure 21 is positioned under the touch control electrodes 51 and can absorb light reflected by a lower surface of the touch control electrodes 51 and light reflected by the light-shielding structure.

The color filter layer 6 includes a color resist layer 61. The color resist layer 61 includes a plurality of color resist units 611. A projection of the touch control electrodes 51 on the array substrate 1 completely falls within a projection of the color resist units 611 on the array substrate 1. The color resist units 611 include red filter units, green filter units, and blue filter units. The red filter units correspond to the red light-emitting units. The green filter units correspond to the green light-emitting units. The blue filter units correspond to the blue light-emitting units.

In this embodiment, the color filter layer 6 further includes a black matrix layer 63 (BM layer). The black matrix layer 63 includes a plurality of openings 621. The color resist units 611 are disposed in the openings 621 and cover edges of the black matrix layer 63. A position of the touch control electrodes 51 corresponds to the black matrix layer 63. The black matrix layer 63 forms the light-shielding structure. A width of each of the slots 22 in the pixel defining layer 2 is less than a width of each of the color resist units 611, which means that an orthographic projection of the slots 22 on the black matrix layer 63 completely falls into the openings 621. Therefore, a size of each of the openings 621 of the black matrix layer 63 is also larger than a size of each of the slots 22 of the pixel defining layer 2, thereby increasing an aperture ratio.

The black matrix layer 63 includes a plurality of light-shielding units. The red filter units, the green filter units, and the blue filter units are spaced apart from each other. The light-shielding units are disposed between the red filter units, the green filter units, and the blue filter units. The light-shielding units correspond to all the touch control electrodes 51. A width of each of the openings 621 is equal to a distance between two adjacent light-shielding units. The width of each of the openings 621 is greater than the width of each of the slots 22.

Providing the light-absorbing structure 21 on the upper surface of the pixel defining layer 2 can increase a contact area between ambient light and the light-absorbing structure 21. In addition, the light-absorbing structure 21 is the black nanostructure, which can increase light absorbability to reduce specular reflection. The light reflected by the touch control electrodes 51 can be absorbed, so as to enhance screen contrast under this synergistic effect. The light-absorbing structure 21 is the concave-convex structure, which is similar to a prism to change light output angles of the display panel 100, thereby increasing viewing angles and increasing readability. Meanwhile, the width of each of the openings 621 is greater than the width of each of the slots 22, which can directly increase the aperture ratio.

The present invention provides the display panel and the display device. An advantage is that the light-absorbing structure formed by the black material adopted by the pixel defining layer can replace a polarizer. The light-absorbing structure is configured to absorb light reflected by the touch control electrodes. The light-shielding structure is disposed on a side of the color filter layer to block, absorb, and reflect the light reflected by the upper surface of the touch control electrodes. Because the polarizer does not need to be provided, a light extraction rate of a light-emitting layer is increased while reducing reflectance of the upper surface of the pixel defining layer. Therefore, the black matrix layer does not need to be provided, or even if the black matrix layer is provided, the size of each of the openings of the black matrix layer is larger than the size of each of the slots of the pixel defining layer, thereby increasing the aperture ratio.

The description above are only preferred embodiments of the invention. It should be pointed out that to those of ordinary skill in the art, various improvements and embellishments may be made without departing from the principle of the present invention, and these improvements and embellishments are also deemed to be within the scope of protection of the present invention.

1. A display panel, comprising:
an array substrate;
a pixel defining layer disposed on the array substrate and comprising a light-absorbing structure; and
a color filter layer disposed on the pixel defining layer and comprising a light-shielding structure corresponding to the light-absorbing structure.

2. The display panel according to claim 1, wherein an upper surface of the pixel defining layer away from the array substrate is defined with a concave-convex structure.

3. The display panel according to claim 2, wherein a cross section of the concave-convex structure is sawtooth-shaped.

4. The display panel according to claim 3, wherein a groove or a protrusion of the concave-convex structure is trapezoidal or columnar.

5. The display panel according to claim 1, wherein a material of the pixel defining layer comprises photosensitive polyimide.

6. The display panel according to claim 1, further comprising a plurality of touch control electrodes disposed between the pixel defining layer and the color filter layer and corresponding to the pixel defining layer.

7. The display panel according to claim 6, wherein the color filter layer comprises a color resist layer comprising a plurality of color resist units, and a projection of the touch control electrodes on the array substrate completely falls within a projection of the color resist units on the array substrate; and
the color resist units in a region corresponding to the touch control electrodes form the light-shielding structure.

8. The display panel according to claim 7, wherein two adjacent color resist units overlap each other to form the light-shielding structure, and the light-shielding structure corresponds to a position of the touch control electrodes.

9. The display panel according to claim 6, wherein the color filter layer comprises a plurality of color resist units arranged at intervals and a black matrix layer disposed between two adjacent color resist units, and a width of the black matrix layer is less than a width of the pixel defining layer; and
the black matrix layer forms the light-shielding structure.

10. The display panel according to claim 9, wherein the pixel defining layer comprises a plurality of slots, and a width of each of the slots is less than a width of each of the color resist units.

11. A display device, comprising a display panel, wherein the display panel comprises:
an array substrate;
a pixel defining layer disposed on the array substrate and comprising a light-absorbing structure; and
a color filter layer disposed on the pixel defining layer and comprising a light-shielding structure corresponding to the light-absorbing structure.

12. The display device according to claim 11, wherein an upper surface of the pixel defining layer away from the array substrate is defined with a concave-convex structure.

13. The display device according to claim 12, wherein a cross section of the concave-convex structure is sawtooth-shaped.

14. The display device according to claim 13, wherein a groove or a protrusion of the concave-convex structure is trapezoidal or columnar.

15. The display device according to claim 11, wherein a material of the pixel defining layer comprises photosensitive polyimide.

16. The display device according to claim 11, wherein the display panel further comprises a plurality of touch control electrodes disposed between the pixel defining layer and the color filter layer and corresponding to the pixel defining layer.

17. The display device according to claim 16, wherein the color filter layer comprises a color resist layer comprising a plurality of color resist units, and a projection of the touch control electrodes on the array substrate completely falls within a projection of the color resist units on the array substrate; and
the color resist units in a region corresponding to the touch control electrodes form the light-shielding structure.

18. The display device according to claim 17, wherein two adjacent color resist units overlap each other to form the light-shielding structure, and the light-shielding structure corresponds to a position of the touch control electrodes.

19. The display device according to claim 16, wherein the color filter layer comprises a plurality of color resist units arranged at intervals and a black matrix layer disposed between two adjacent color resist units, and a width of the black matrix layer is less than a width of the pixel defining layer; and
the black matrix layer forms the light-shielding structure.

20. The display device according to claim 19, wherein the pixel defining layer comprises a plurality of slots, and a width of each of the slots is less than a width of each of the color resist units.
